(19) United States
(12) Patent Application Publication
(10) Pub. No.: US 2019/0107579 A1
(43) Pub. Date: Apr. 11, 2019

(54) UNIQUE METHOD FOR FINDING THE STATOR CORE AND ROTATIONAL LOSSES, AND THE IMPEDANCES OF A FIXED-FREQUENCY INDUCTION MACHINE FROM THE DIMENSIONS OF ITS PER-PHASE IMPEDANCE CIRCLE

(71) Applicant: Donald Skaar, San Diego, CA (US)

(72) Inventor: Donald Skaar, San Diego, CA (US)

(21) Appl. No.: 15/729,033

(22) Filed: Oct. 10, 2017

(51) Int. Cl. G01R 31/34

(52) U.S. Cl. CPC G01R 31/34

(57) ABSTRACT

The present disclosure is directed to finding the six impedances shown in IEEE Standard 112 without using the blocked rotor test.

### FIELD

The present invention relates generally to the finding of the six impedances of an induction machine electrical model without using the blocked rotor test.

### BACKGROUND

It is long been the procedure to use the well-known blocked rotor test for finding the six impedances shown in the IEEE Standard 112. The blocked rotor test can be awkward to employ and there are often issues with proper test frequency-selection. Therefore there is a need for an improved test methodology.

### SUMMARY

The present disclosure is directed to a method of finding values for the six impedances in FIG. 2 of IEEE Standard 112. With the machine running at normal operating temperature and at rated voltage and frequency, the steps consist generally of the following (see FIG. 1):
1) At no load, measure and record the power, current and slip. Calculate R_{NL} and Z_{NL}.
2) Apply a load to the machine until the pf (power factor) is 0.5 (wattmeter W_{A} reads zero);

record the power (P₁) and current (I₁) and calculate R_{OP1} and X_{OP1}.
3) Load the machine so R_{OP2} is as equal to R_{OP1} as instrument accuracy allows; record the power and current, then calculate X_{OP2}.
4) Drive the machine until s=0 and record the power.

The measurements collected from these steps (see the example below) provide all six impedances of the model from IEEE Standard 112.

This summary is not intended to limit the scope of the invention, or describe each embodiment, implementation, feature or advantage of the invention.

### BRIEF DESCRIPTION OF THE DRAWINGS

FIG. 1 is The Per Phase Impedance Circle for an Induction Machine used in the method claimed herein.

### DESCRIPTION OF THE PREFERRED EMBODIMENTS

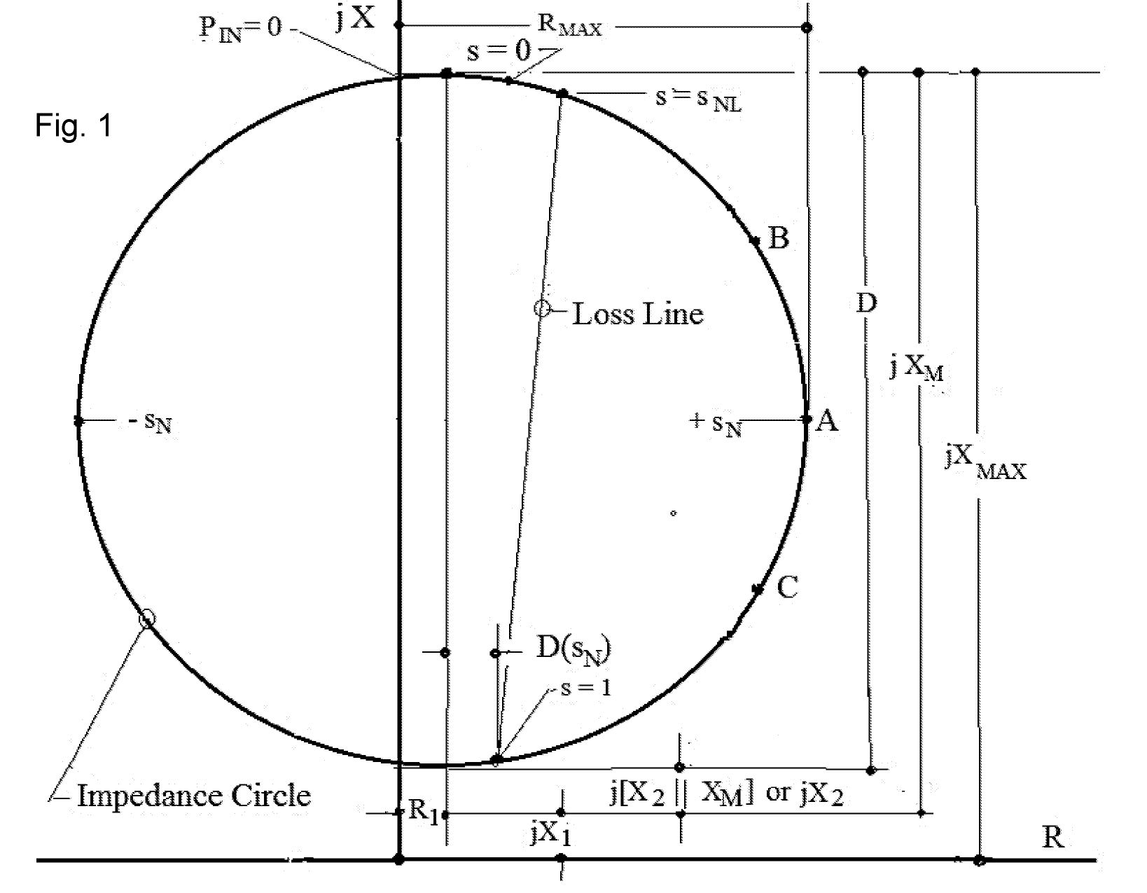

Disclosed herein is a method used to find values for the six impedances shown in FIG. 2 of IEEE Standard 112, while avoiding the blocked rotor test. FIG. 1 is the graphical equivalent of the model of IEEE 112.

The proposed method uses measurements taken on a fixed-frequency, freely-rotating machine operating at rated voltage and frequency. FIG. 1, while of help in understanding the general method and the equations used, is not to scale: D>>[X₁+(X₂∥X_{M})]>R₁. Also, the point at (s=0) does not reflect the clockwise shift in slip due to the effect of R_{fe}. The validity of the method is justified by using ‘lab measurements’ generated by a computer analysis of the Class B machine whose six impedances and other characteristics are postulated below. Although per-phase power is used in the ‘Measurements’ and ‘Calculations’, it is assumed that the two wattmeter method (W_{A} and W_{C}) is used in the lab, and that the DC resistance, R_{1DC}≈R₁, has been measured and recorded.

### Measurments and Calculations

### Postulated Data for a Class B Machine

f=60 Hz; Vₗᵢₙₑ=440 V; Vₚ=254 V; R₁=0.50Ω; X₁=X₂=1.00Ω;

X_{M}=39.0Ω; R₂=0.640Ω; R_{fe}=320Ω; P_{WF}=96.0 W; P_{RFE}=192 W.

### Measurements

a) OP₁: P₁=931 W; I₁=7.33 A; R_{OP1}=17.3Ω; X_{OP1}=30.0Ω;
b) OP₂: P₂=2530 W; I₂=12.1 A; R_{OP2}=17.3Ω; X_{OP2}=11.9Ω;
c) s=0: P₀=211 W
d) No load: P_{NL}=307 W; Iₙₗ=6.44 A: s_{NL}=0.001;

### Calculations

From d): R_{NL}=P_{NL}/(Iₙₗ)²=7.40Ω; Z_{NL}=Vₚ/Iₙₗ=39.4Ω; 1)

X_{MAX}=[(Z_{NL})²+(R_{NL}−R₁)²]^{0.5}=40.0Ω;

From FIG. 1: X_{c}=(X_{OP1}+X_{OP2})/2 =21.0Ω; 2)

D=2(X_{MAX}−X_{C})=38.0Ω;

[X₁+(X₂∥X₂)]≈(X₁+X₂)=(X_{MAX}−D)=2.00Ω; for Class B,

(X₁=X₂)=(X₁+X₂)/2=1.00Ω; from FIG. 1,

X_{M}=[(D+(X₂∥X₂)]=39.0Ω;
3) From c) and d):

P_{WF}=[P_{NL}−P₀]=96 W; P_{RFE}=[P_{NL}−P_{WF}(Iₙₗ²)(R₁)]=190 W

R_{fe}=(V_{rfe})²/P_{RFE}; V_{rfe}=Vₚ(X_{M})/(X_{M}+X₁)=248 V; so R_{fe}=324Ω;

P_{WF}=D(Iₙₗ)²(S_{NL}/S_{N}); so s_{N}=D(Iₙₗ)²(s_{NL}/P_{WF})=38.0(6.44)²(0.001/96.0)=0.0164; by definition: s_{N}=R₂/[X_{M}+(X₂)∥X₂,)] so R₂=s_{N}[X_{M}+(X₂∥X_{M})]=0.0164(40)=0.656Ω. 4)

The correlation between the calculated impedance and per phase power values with those postulated above is good with the exception of R₂, which is 2.5 percent high. A higher value of R₂ may be fortuitous since the IEEE 112 model does not account for rotor and stray losses:

rₙ=sₙ/(1+sₙ)² where sₙ=s/s_{N} and s is per unit slip. For very small s,

rₙ≈sₙ and so P_{WF}=(Iₙₗ)²(D)(s_{NL}/s_{N}); solving for s_{N}:

s_{N}≈[(Iₙₗ)²(D)(s_{NL})]/P_{WF}=0.0164; by definition for the IEEE Standard model:

s_{N}=[R₂/(Xₘ+X₂)]; so R₂=s_{N}(X_{M}+X₂)=0.656Ω.

The correlation between the calculated impedance values with those previously postulated from is good with the exception of R2, which is 3.44 percent high. A higher value of R2 may be fortuitous since the IEEE 112 model does not account for rotor core and stray losses. It is not necessary to select OP₁ as shown although it is recommended. If OP₁ is chosen with R_{OP1} too small (very light load), OP₂ may overload the machine. If OP₁ is too close to s_{N} (see FIG. 1), X_{OP1} changes too rapidly for small changes in R_{OP1}.

What is claimed is:

1. A method for finding the numerical values of the rotational losses, the stator core loss and the impedances X_{M}, X₁, X₂, R_{FE} and R₂ for a multiphase induction machine, the method comprising:
operating a freely-rotating induction machine at its rated voltage and rated fixed-frequency;
obtaining rotational losses, stator core loss and R_{FE} from power readings at no load and synchronous speed;
using FIG. 1 to determine the values of X_{MAX}, D and sX; and,
calculating the values of X_{M}, X₁, X₂ and R₂, where X_{M}=(X_{MAX}+D)/2, X₁=[X_{MAX}−X_{M}], X₂=[(X_{MAX}−D)−X₁] and R₂=[s_{N}(X_{MAX})].
